(19) United States
(12) Patent Application Publication
(10) Pub. No.: US 2018/0013051 A1
(43) Pub. Date: Jan. 11, 2018

(54) METHOD FOR FORMING TELLURIUM/TELLURIDE NANOWIRE ARRAYS AND TELLURIUM/TELLURIDE NANOWIRE THERMOELECTRIC DEVICES

(71) Applicant: NATIONAL TSING HUA UNIVERSITY, HSINCHU (TW)

(72) Inventors: Zong-Hong LIN, HSINCHU (TW); Ting-Mao CHOU, New Taipei City (TW); Ying-Chun LI, New Taipei City (TW); Yun-Ting JAO, Hsinchu City (TW)

(21) Appl. No.: 15/338,468

(22) Filed: Oct. 31, 2016

(30) Foreign Application Priority Data
Jul. 11, 2016 (TW) 105121774

(51) Int. Cl. H01L 35/34; C09D 5/24; H01L 35/04; C09D 1/00; C01B 19/00; C01B 19/02; C09D 5/26

(52) U.S. Cl. CPC H01L 35/34; C01B 19/02; C09D 5/24; C09D 5/26; C09D 1/00; C01B 19/007; H01L 35/04; C01P 2004/03; C01P 2004/16; C01P 2006/32; C01P 2006/40

(57) ABSTRACT

A method for forming tellurium/telluride nanowire arrays on a conductive substrate is provided. The method is used for forming tellurium/telluride nanowire thermoelectric materials and producing thermoelectric devices, and the method includes: preparing a conductive substrate; preparing a mixture solution comprising a tellurium precursor and a reducing agent; immersing the conductive substrate into the mixture solution; reacting the tellurium precursor and the reducing agent for forming a plurality of tellurium/telluride nanowires on the conductive substrate; and arranging the tellurium/telluride nanowires for forming tellurium/telluride nanowire arrays.

### RELATED APPLICATIONS

This application claims priority to Taiwan Application Serial Number 105121774, filed Jul. 11, 2016, which is herein incorporated by reference.

### BACKGROUND

### Technical Field

The present disclosure relates to a method for forming tellurium/telluride nanowire arrays and tellurium/telluride thermoelectric devices. More particularly, the present disclosure relates to a method for forming large or small scale tellurium/telluride nanowire arrays on various conductive substrates and tellurium/telluride nanowire thermoelectric devices formed by the method.

### Description of Related Art

Electricity is the necessity of everyday life. Many electric devices are driven by the electricity. There are various methods for generating electricity nowadays, such as solar cell power generation, wind power generation, hydraulic power generation and nuclear electricity generation. Owing to the resources depletion and the environmental issue, new kinds of electricity generation methods have been much concerned.

Thermoelectric devices are widely used in such as a heating/cooling system and a heat recovery/electricity generation system. The thermoelectric device is main equipment in the frozen industry, the air conditioning industry, the waste heat recovery industry, the temperature control industry and the thermoelectric power generation system. The operation of the thermoelectric device is based on the thermoelectric effect. The thermoelectric effect is a phenomena that transferring the thermal energy to the electrical energy or transferring the electrical energy to the thermal energy. The basic principle of the thermoelectric effect is that when a temperature difference is occurred on a thermoelectric material, an electromotive force is generated. The electromotive force can generate a current output thereby providing electricity. For example, in a thermoelectric device including a p-type thermoelectric material and a n-type thermoelectric material, a heat transportation is through the electrons and the holes flowing through the p-type or n-type thermoelectric material.

The thermoelectric device can transfer the thermal energy to the electrical energy without any external forces and mechanical energy, and can reduce energy loss, enhance energy usage and reduce thermal pollution. The efficiency of a thermoelectric material can be defined by a thermoelectric figure of merit ZT=S²σT/(K), where S is thermoelectric power or Seebeck coefficient, σ is electrical conductivity T is temperature and K is thermal conductivity. The parameters in the ZT are interacted, therefore an ideal thermoelectric material is hard to find. For reaching a maximum value of ZT, the ideal thermoelectric material should have high electrical conductivity for preventing electric power loss and low thermal conductivity for keeping the stability of the temperature difference on two sides of the thermoelectric material.

Thus, nanotechnology brings a new future to the thermoelectric material. When a dimension of a material is lowered to the nano scale range, a ratio of the surface atoms to the non-surface atoms is dramatically increased, thereby dramatically enhancing the surface effect. Furthermore, in the nano scale range, the quantum size effect of the material will also be increased. Therefore, there are distinct differences of the material characteristics between the bulk materials and the nano-scale materials. The nano-scale materials have new physical characteristics and interface phenomena, thus it is expected to break the bottleneck on low thermoelectric conversion efficiency of the thermoelectric material. For example, in the nano scale range, the lattice of the material will enhance the scatter frequency of the phonon, thereby lowering the thermal conductivity k, and the thermoelectric conversion efficiency can be enhanced. The application fields of the thermoelectric materials will be increased due to the increase of the thermoelectric conversion efficiency in the nano scale range. For example, the thermoelectric material can be applied in the commodity industry, the semiconductor industry or the medical industry. Furthermore, the thermoelectric material can also be used to recovery the waste thermal energy of industrial thermal energy (thermal energy from industrial emissions, waste material energy, heat exchanging energy), vehicle thermal energy (fuel engine thermal energy, engine thermal energy), environmental thermal energy (solar thermal energy, geothermal energy) and other thermal energy (heat water energy, residence thermal energy).

Although the thermoelectric material in the nano scale range can have higher thermoelectric conversion efficiency, however, nano-scale materials are such new materials that the material characteristics thereof cannot be totally understood and grasped. Complicated manufacturing processes are required for producing a large scale (area) nano-scale material for real use, thus the manufacturing cost is still high and it is not propitious to mass production.

Therefore, there is a need to develop a simple method that is capable of mass producing thermoelectric devices having large area in the nano scale range.

### SUMMARY

According to one aspect of the present disclosure, a method for forming tellurium/telluride nanowire arrays on a conductive substrate is provided. The method is used for forming tellurium/telluride nanowire thermoelectric materials on conductive substrates and producing thermoelectric devices, and the method includes: preparing a conductive substrate; preparing a mixture solution comprising a tellurium precursor and a reducing agent; immersing the conductive substrate into the mixture solution; reacting the tellurium precursor and the reducing agent for forming a plurality of tellurium/telluride nanowires on the conductive substrate; and arranging the tellurium/telluride nanowires for forming tellurium/telluride nanowire arrays. In this method, the conductive substrate can be rigid or flexible.

According to another aspect of the present disclosure, a tellurium/telluride nanowire thermoelectric device is provided. The tellurium/telluride nanowire thermoelectric device includes a first electrode, at least one tellurium/telluride nanowire array and a second electrode. The at least one tellurium/telluride nanowire array is formed on the first electrode. The second electrode is formed on the at least one tellurium/telluride nanowire array.

### BRIEF DESCRIPTION OF THE DRAWINGS

The present disclosure can be more fully understood by reading the following detailed description of the embodiment, with reference made to the accompanying drawings as follows:

FIG. 1 is a flow chart showing a method for forming tellurium/telluride nanowire arrays on a conductive substrate;

FIG. 2 shows tellurium/telluride nanowire arrays formed on a conductive substrate having a mesh shape;

FIG. 3 shows tellurium/telluride nanowire arrays formed on a conductive substrate having a sheet shape;

FIG. 4A is a Scanning Electron Microscopy (SEM) diagram showing tellurium/telluride nanowire arrays formed on a conductive substrate having a mesh shape and made from carbon fibers;

FIG. 4B is a Scanning Electron Microscopy diagram showing the tellurium/telluride nanowires of FIG. 4A;

FIG. 5A is a Scanning Electron Microscopy diagram showing tellurium/telluride nanowire arrays formed on a conductive substrate having a sheet shape and made from Aluminum;

FIG. 5B is a Scanning Electron Microscopy diagram showing the tellurium/telluride nanowires of FIG. 5A;

FIG. 6 is a schematic view showing a tellurium/telluride nanowire thermoelectric device according to one embodiment of the present disclosure;

FIG. 7 shows an application example of the tellurium/telluride nanowire thermoelectric device of FIG. 6;

FIG. 8A shows voltage outputs varied with temperature differences of the tellurium/telluride nanowire thermoelectric device of FIG. 6;

FIG. 8B shows current outputs varied with temperature differences of the tellurium/telluride nanowire thermoelectric device of FIG. 6;

FIG. 9 shows a tellurium/telluride nanowire thermoelectric device constructed by stacking of a p-type tellurium/telluride nanowire array and a n-type tellurium/telluride nanowire array;

FIG. 10 shows an application example of the tellurium/telluride nanowire thermoelectric device of FIG. 9;

FIG. 11 shows a tellurium/telluride nanowire thermoelectric device constructed by crossly stacking multiple p-type tellurium/telluride nanowire arrays and multiple n-type tellurium/telluride nanowire arrays;

FIG. 12 shows voltage outputs varied with temperature differences of the tellurium/telluride nanowire thermoelectric device of FIG. 11;

FIG. 13 shows an application example of the tellurium/telluride nanowire thermoelectric device of FIG. 11;

FIG. 14 shows another structural example of the tellurium/telluride nanowire thermoelectric device of FIG. 11;

FIG. 15 shows an application example of the tellurium/telluride nanowire thermoelectric device of FIG. 14;

FIG. 16 shows another application example of the tellurium/telluride nanowire thermoelectric device of FIG. 14; and

FIG. 17 shows still another application example of the tellurium/telluride nanowire thermoelectric device of FIG. 14.

### DETAILED DESCRIPTION

It is a purpose of the present disclosure to provide a method for forming tellurium/telluride nanowire thermoelectric materials and devices. The present disclosure demonstrates a simple method for forming tellurium/telluride nanowire arrays on a conductive substrate. The method can be performed at room temperature to produce tellurium/telluride nanowire thermoelectric device having large area thus it is favorable for mass production. Through the method, the electrical conductivity can be enhanced and the thermal conductivity can be reduced for increasing the thermoelectric conversion efficiency by the tellurium/telluride nanowire thermoelectric materials in the nano scale range.

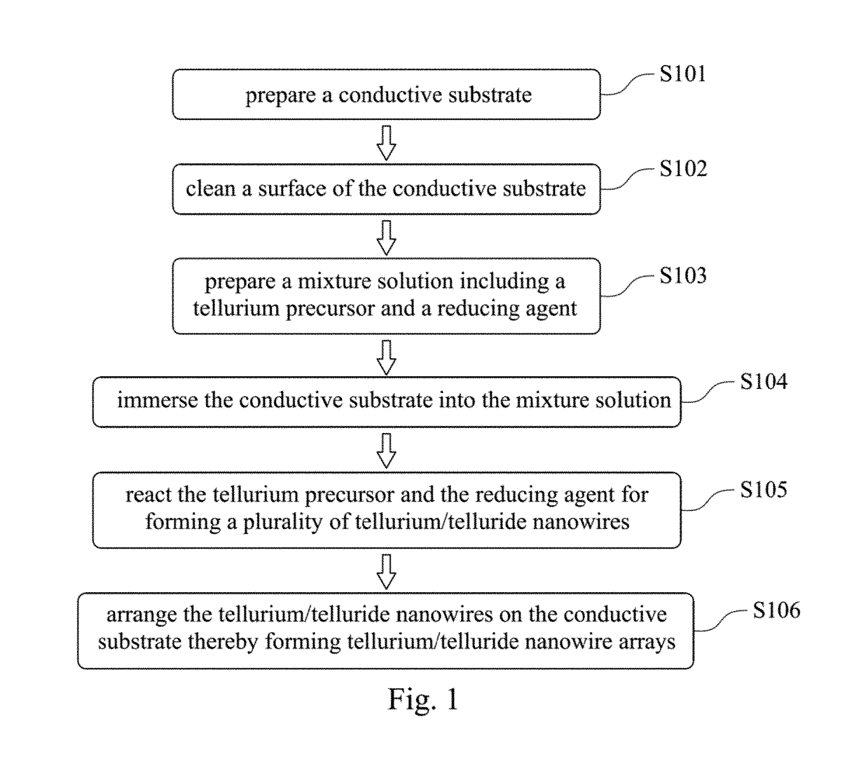

FIG. 1 is a flow chart showing a method for forming tellurium/telluride nanowire arrays on a conductive substrate. The method includes the following steps.

A step S101 for preparing a conductive substrate.

A step S102 for cleaning a surface of the conductive substrate.

A step S103 for preparing a mixture solution comprising a tellurium precursor and a reducing agent.

A step S104 for immersing the conductive substrate into the mixture solution.

A step S105 for reacting the tellurium precursor and the reducing agent for forming a plurality of tellurium/telluride nanowires.

A step S106 for arranging the tellurium/telluride nanowires on the conductive substrate thereby forming tellurium/telluride nanowire arrays.

In the step S103, the tellurium precursor can be made from Te [symbol] TeO [symbol] TeO₂ [symbol] TeO₃ [symbol] Te₂O₅ [symbol] H₂TeO₃ [symbol] K₂TeO₃ [symbol] Na₂TeO₃ [symbol] H₂TeO₄ [symbol] K₂TeO₄ [symbol] Na₂TeO₄ [symbol] H₂Te [symbol] NaHTe [symbol] (NH₄)₂Te [symbol] TeCl₄ [symbol] MezTe [symbol] [symbol] Zn(TePh)₂(tmeda) [symbol] (tmeda=N,N,N′,N′-teramethylethylenediamine) or Ph₂SbTeR (R=Et, Ph). In one example, the mixture solution can be formed by pouring the tellurium precursor powders into the reducing agent solution.

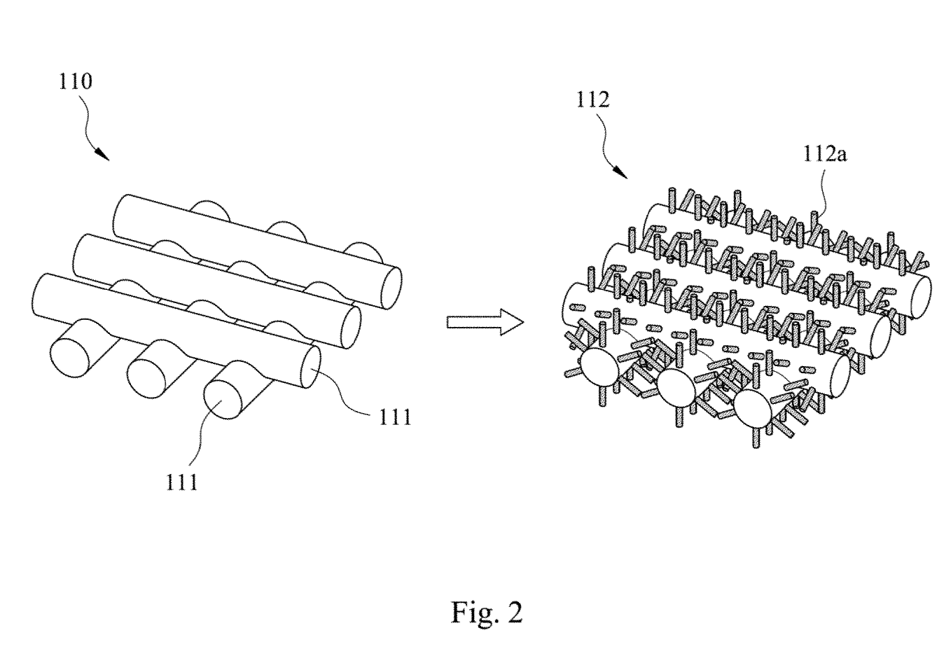

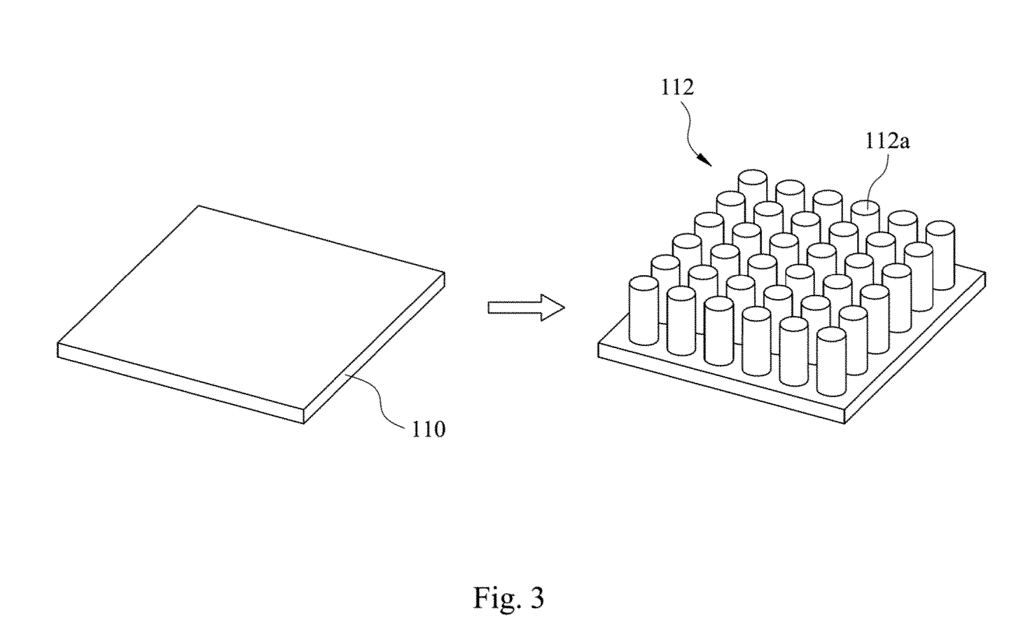

In the Step S101, the conductive substrate can be fiber shaped, thin-film shaped, bulk shaped, sheet shaped, irregularly shaped, mesh shaped or porously shaped. For example, in FIG. 2, the tellurium/telluride nanowire arrays 112 are formed on the conductive substrate 110 with a mesh shape, and in FIG. 3, the tellurium/telluride nanowire arrays 112 are formed on the conductive substrate 110 with a sheet shape. In FIG. 2, the conductive substrate 110 with a mesh shape is formed by a plurality of substrate units 111 which are crossly arranged. Thus, a plurality of tellurium/telluride nanowires 112a are surrounded on the surface of each of the substrate units 111, thereby forming the tellurium/telluride nanowire arrays 112. In FIG. 3, a plurality of tellurium/telluride nanowires 112a are arranged on the conductive substrate units 110, thereby forming the tellurium/telluride nanowire arrays 112.

In the step S105 and the step S106 of FIG. 1, the length and the width of the tellurium/telluride nanowires 112a can be controlled by adjusting the concentration ratio of the tellurium precursor and the reducing agent.

In some embodiments, the conductive substrate 110 can be fiber shaped, thin-film shaped, bulk shaped, sheet shaped, irregularly shaped, mesh shaped or porously shaped. The conductive substrate 110 can also be made from lithium, rubidium, potassium, cesium, barium, strontium, calcium, sodium, magnesium, aluminum, manganese, beryllium or carbon which has stronger reducibility. When the conductive substrate 110 is made from such kind of materials having stronger reducibility, the tellurium/telluride nanowires 112a can be well arranged.

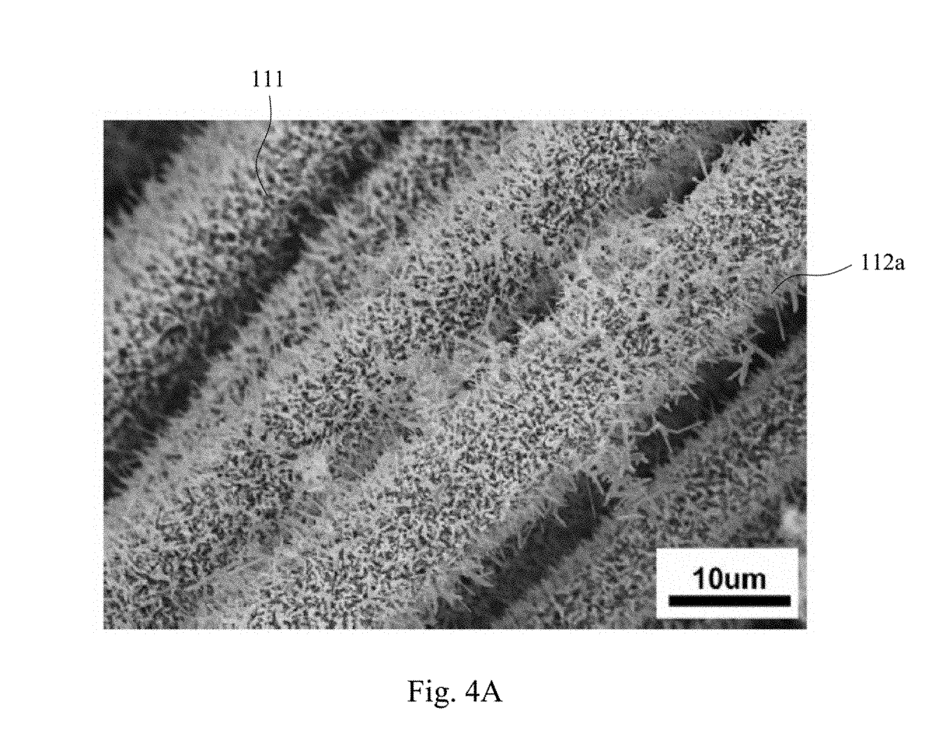

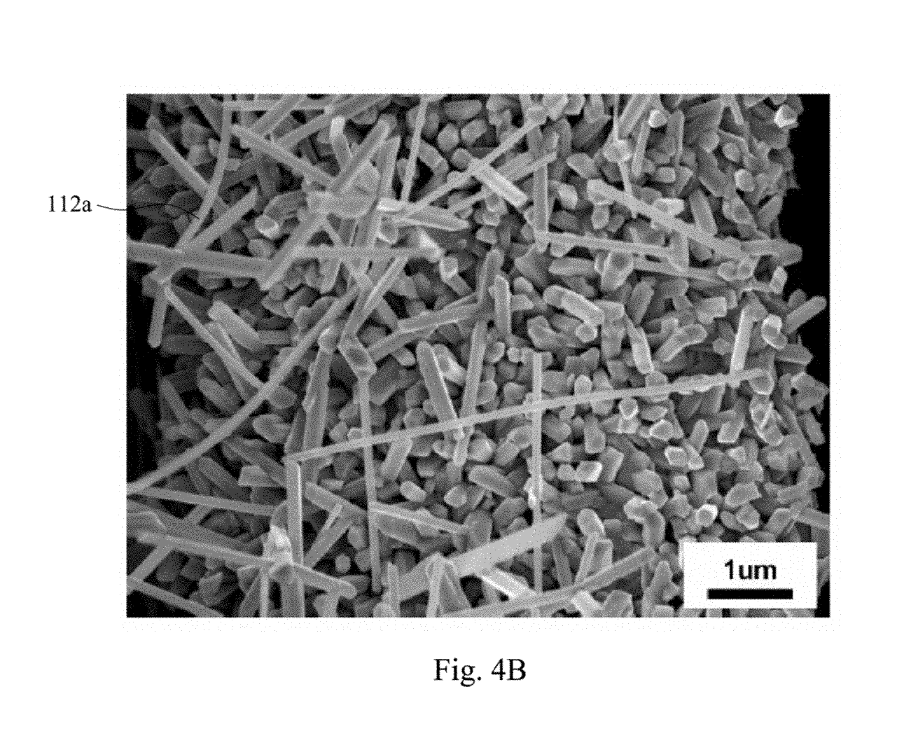

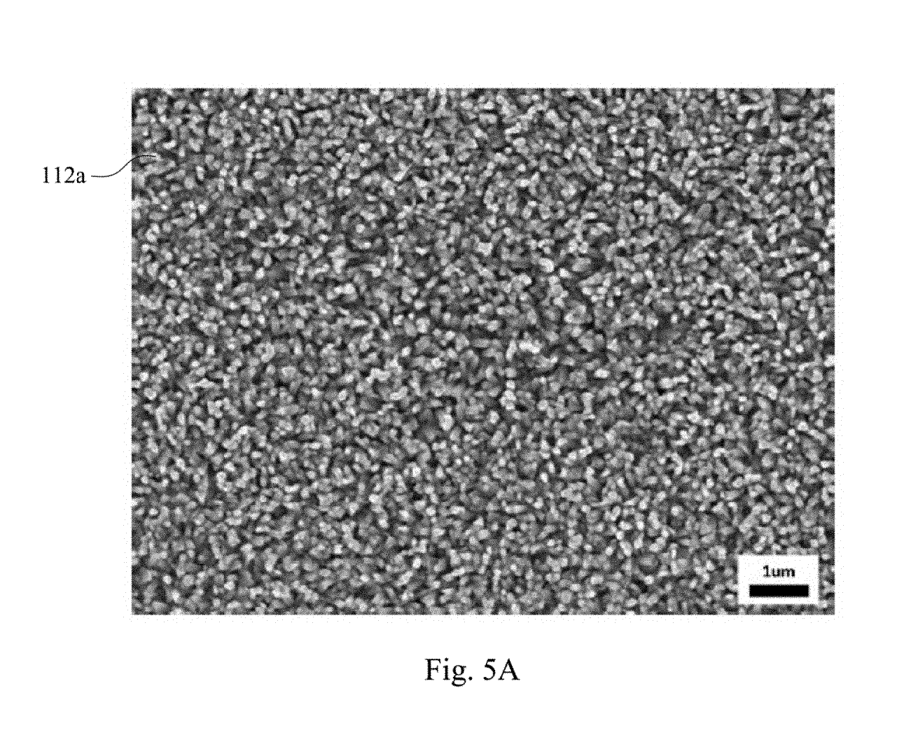

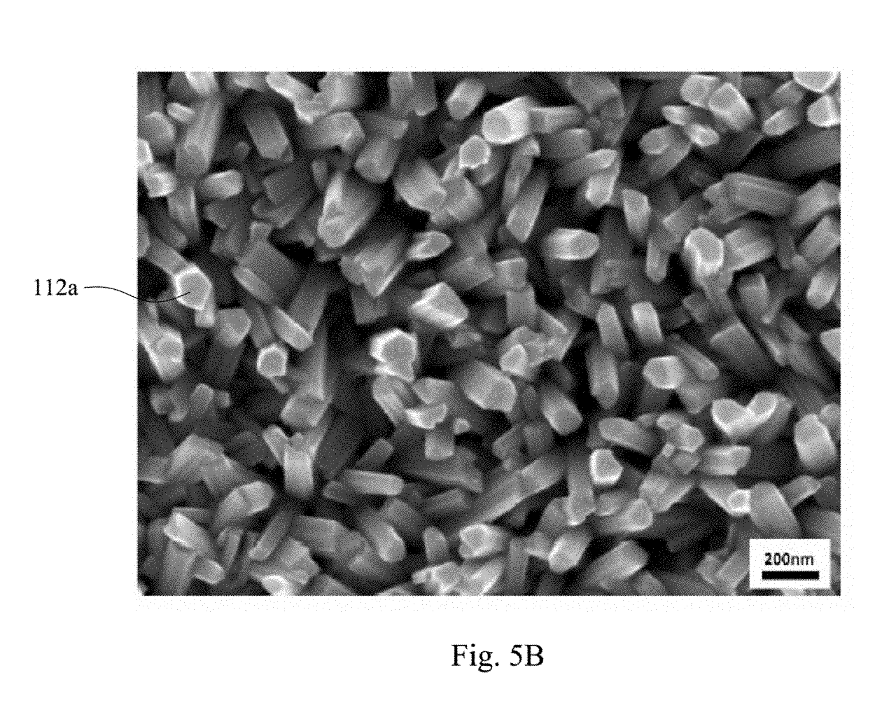

FIG. 4A is a Scanning Electron Microscopy (SEM) diagram showing tellurium/telluride nanowire arrays formed on a conductive substrate having a mesh shape and made from carbon fibers; FIG. 4B is a Scanning Electron Microscopy diagram showing the tellurium/telluride nanowires of FIG. 4A; FIG. 5A is a Scanning Electron Microscopy diagram showing tellurium/telluride nanowire arrays formed on a conductive substrate having a sheet shape and made from Aluminum; FIG. 5B is a Scanning Electron Microscopy diagram showing the tellurium/telluride nanowires of FIG. 5A.

In FIGS. 4A and 4B, it is shown that a plurality of tellurium/telluride nanowires 112a are surrounded on the surface of each of the substrate units 111 of the conductive substrate 110 which is fiber shaped and made from carbon. The tellurium/telluride nanowires 112a are arranged to form tellurium/telluride nanowire arrays 112.

Similarly, in FIGS. 5A and 5B, it is shown that a plurality of tellurium/telluride nanowires 112a are arranged on the conductive substrate 110 which is sheet shaped and made from Aluminum. The tellurium/telluride nanowires 112a are arranged to form tellurium/telluride nanowire arrays 112.

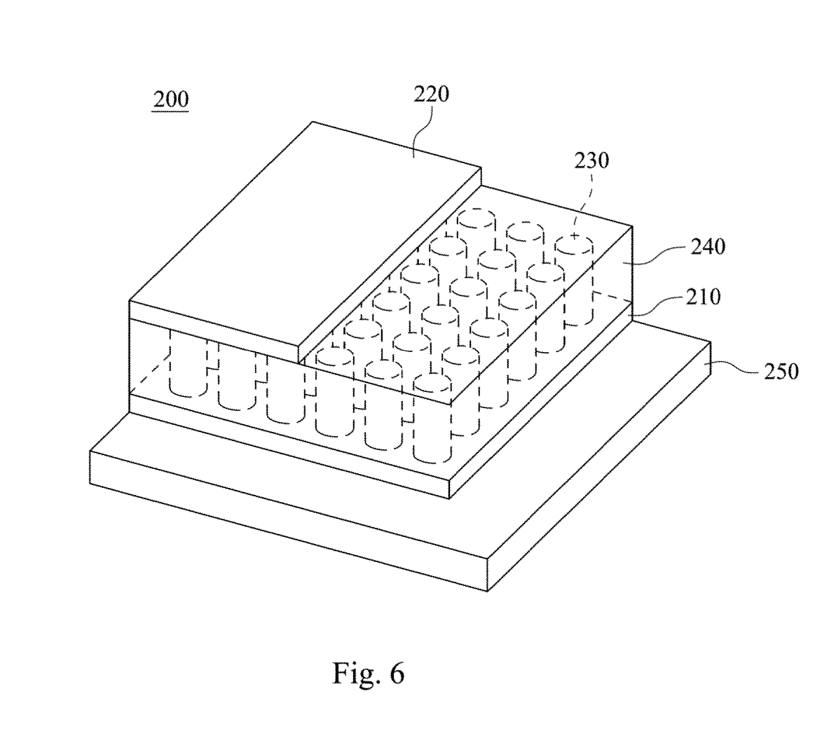

FIG. 6 is a schematic view showing a tellurium/telluride nanowire thermoelectric device 200 according to one embodiment of the present disclosure. The thermoelectric device 200 can be easily constructed by tellurium/telluride nanowire arrays 230 formed by the aforementioned method. For example, in FIG. 6, at least one tellurium/telluride nanowire array 230 is formed on the first electrode 210. Both of the conductive substrate 110 of the aforementioned embodiment and the first electrode 210 of this embodiment are good conductors of electricity, thus the conductive substrate 110 in the aforementioned embodiments can be acted as the first electrode 210 in this embodiment.

Then, a colloidal metal or a solid metal can be coated or evaporated on the tellurium/telluride nanowire arrays 230 as a second electrode 220, thereby forming an essential structure of the tellurium/telluride nanowire thermoelectric device 200.

The second electrode 220 can be a metal, a conductive oxide or a conductive polymer, it can be made from an Indium tin oxide (ITO), Gold (Au), Silver (Ag), Platinum (Pt), Aluminum (Al), Nickel (Ni), Copper (Cu), Titanium (Ti), Chromium (Cr), Selenium (Se) or alloys thereof. Preferably, a conductive polymer 240 can be formed between the tellurium/telluride nanowire arrays 230 and the second electrode 220, it can be made from polyaniline (PANI), polythiophene (PTH), poly (3, 4-ethylenedioxythiophene):poly (styrenesulfonate) (PEDOT:PSS), polyacetylene (PA), polypyrrole (PPY), polycarbazoles (PC) or polyphenylenevinylene (PPV).

The conductive polymer 240 can enhance the electrical conductivity of the tellurium/telluride nanowire thermoelectric device 200. When a temperature difference is formed between the top and the bottom of the tellurium/telluride nanowire arrays 230, an electromotive force is generated thereby generating a voltage difference. For balancing charges, the free electrons of the first electrode 210 and the second electrode 220 flow to an external circuit and produce a current output.

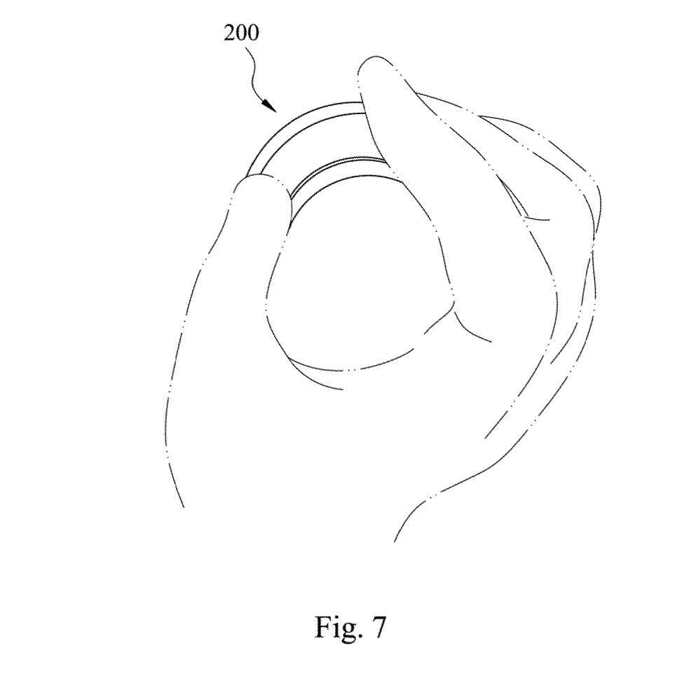

FIG. 7 shows an application example of the tellurium/telluride nanowire thermoelectric device 200 of FIG. 6. In FIG. 6, a base material 250 is placed below the first electrode 210. In one example, the tellurium/telluride nanowire thermoelectric device 200 is flexible and can be adapted with various objects having curved or irregular surfaces.

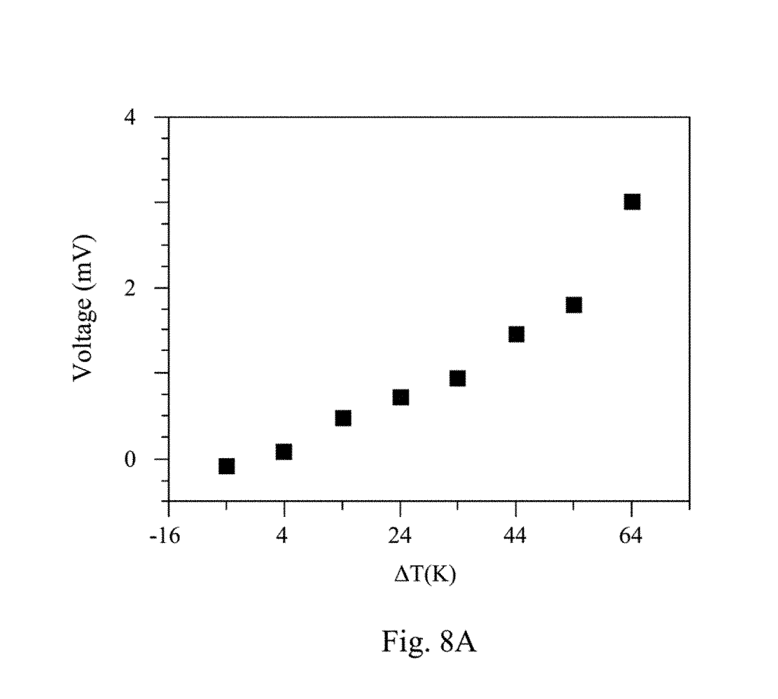

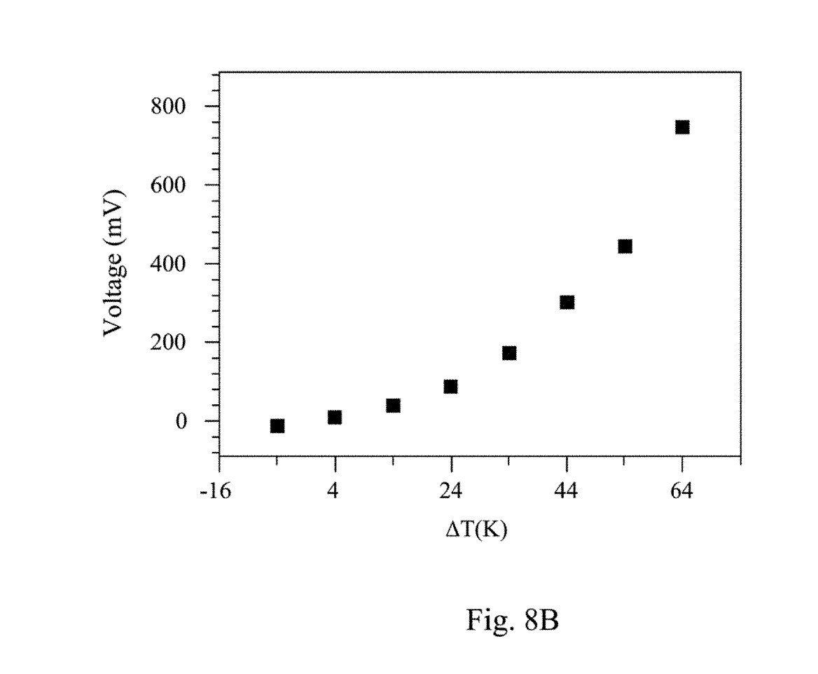

FIG. 8A shows voltage outputs varied with temperature differences of the tellurium/telluride nanowire thermoelectric device 200 of FIG. 6; FIG. 8B shows current outputs varied with temperature differences of the tellurium/telluride nanowire thermoelectric device 200 of FIG. 6. In the embodiment, the tellurium/telluride nanowire thermoelectric device 200 is used for generating electricity. The dimension of the tellurium/telluride nanowire thermoelectric device 200 is 0.5 cm×0.5 cm, and the temperature difference is from −6° C. to 64° C. In the temperature difference of 64° C., the voltage output can reach 3.2 mV, and the current output can reach 780 nA. The voltage output or the current output can be increased by increasing the dimension of the tellurium/telluride nanowire thermoelectric device 200. Moreover, when the temperature difference is continuously occurred between the top and the bottom of the tellurium/telluride nanowire thermoelectric device 200, a continuous and stable electrical output can be generated.

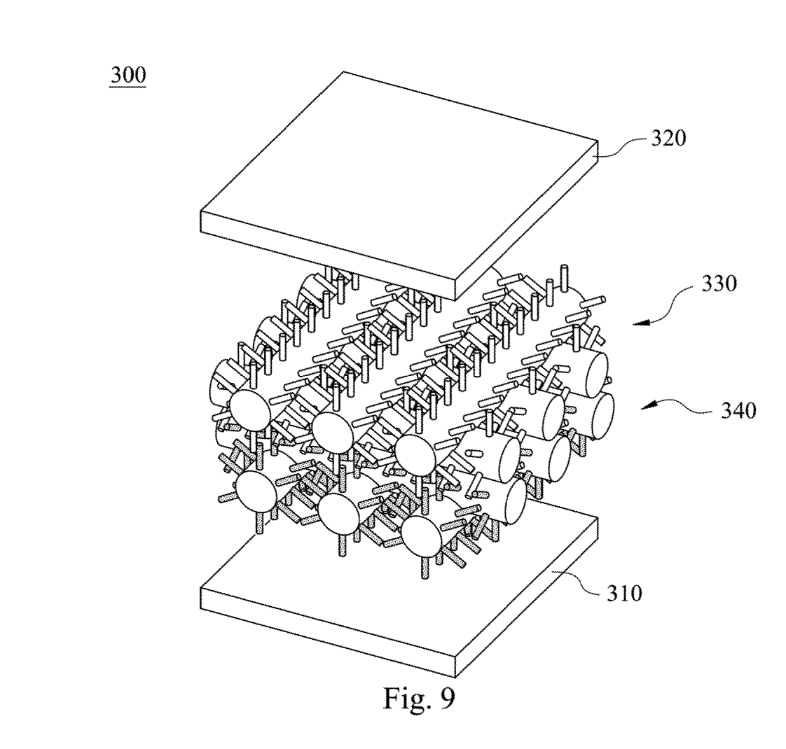

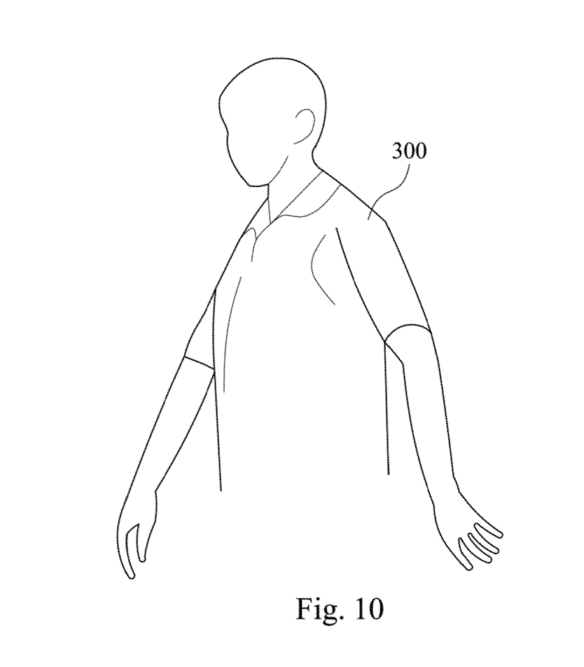

FIG. 9 shows a tellurium/telluride nanowire thermoelectric device 300 constructed by stacking of a p-type tellurium/telluride nanowire array 330 and a n-type tellurium/telluride nanowire array 340; FIG. 10 shows an application example of the tellurium/telluride nanowire thermoelectric device 300 of FIG. 9. The tellurium/telluride nanowire thermoelectric device 300 has wide applications. For example, in FIG. 9, a p-type tellurium/telluride nanowire array 330 and a n-type tellurium/telluride nanowire array 340 are stacked and located between the first electrode 310 and the second electrode 320. The first electrode 310 can be acted as the aforementioned conductive substrate 110. In FIGS. 9 and 10, the first electrode 310 is fiber-shaped and is made from carbon. In FIG. 10, the tellurium/telluride nanowire thermoelectric device 300 can be formed as a carbon fiber cloth. Therefore, it is capable of collecting thermal energy when applying the tellurium/telluride nanowire thermoelectric device 300 to a smart cloth or a fire-entry cloth.

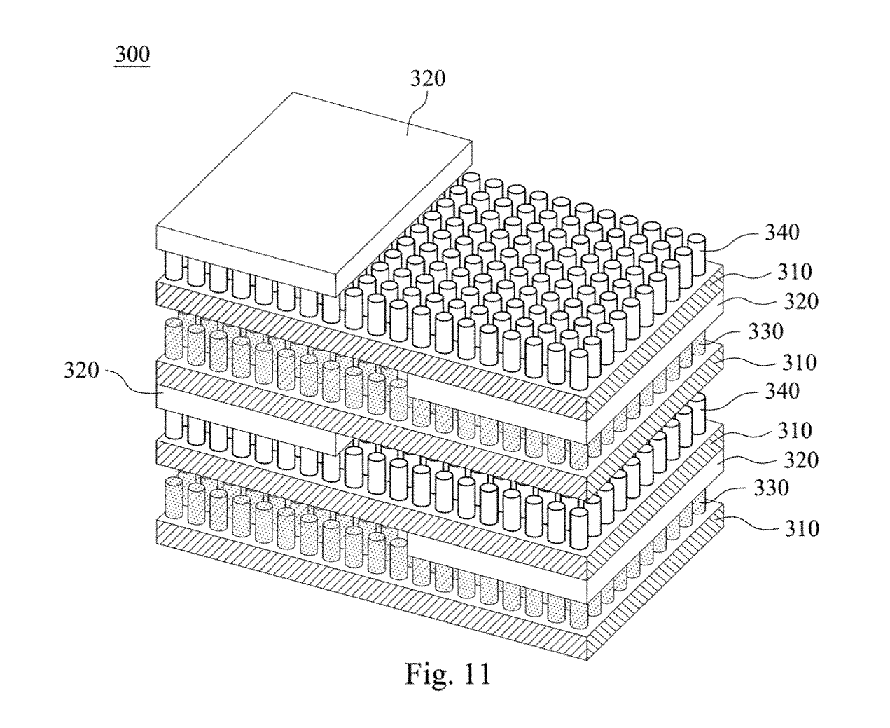

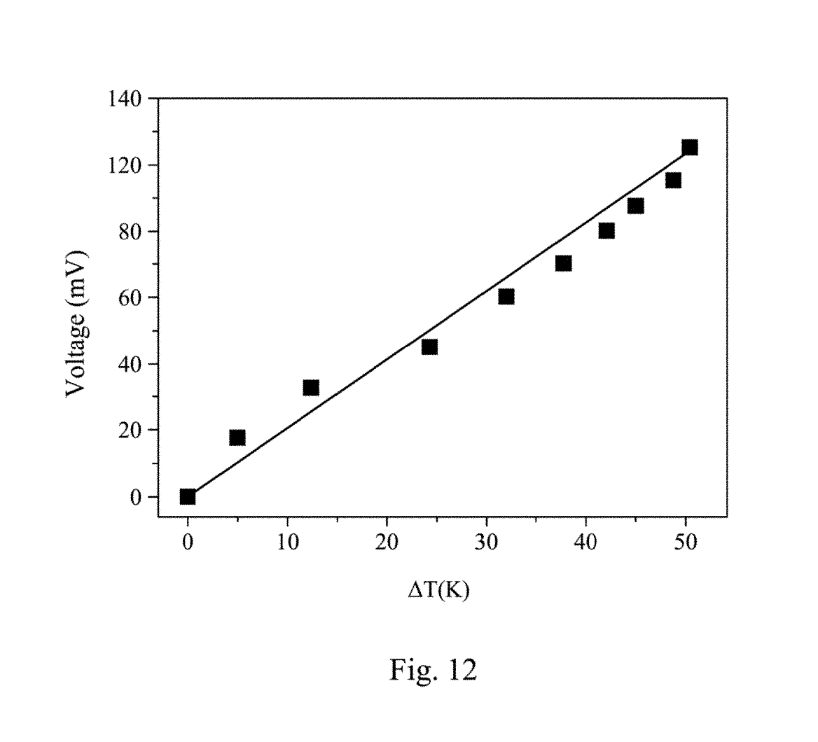

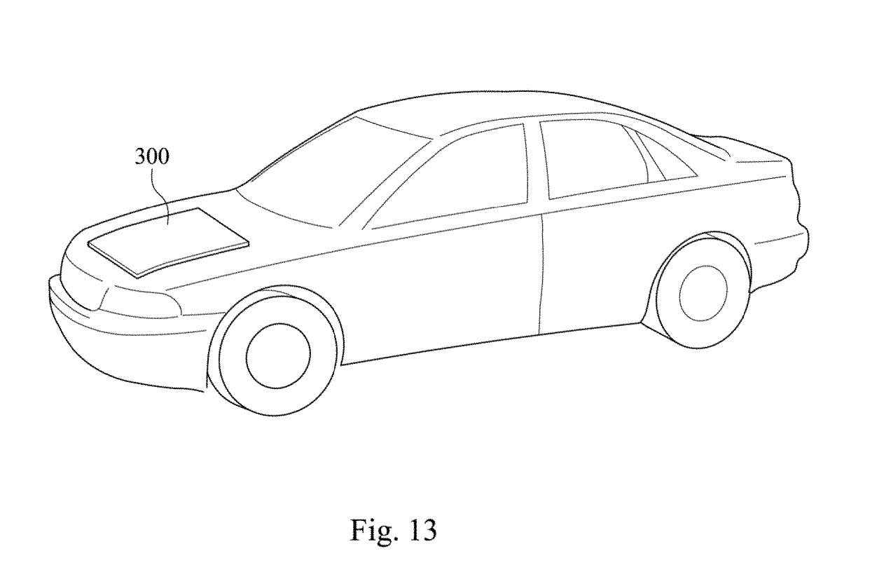

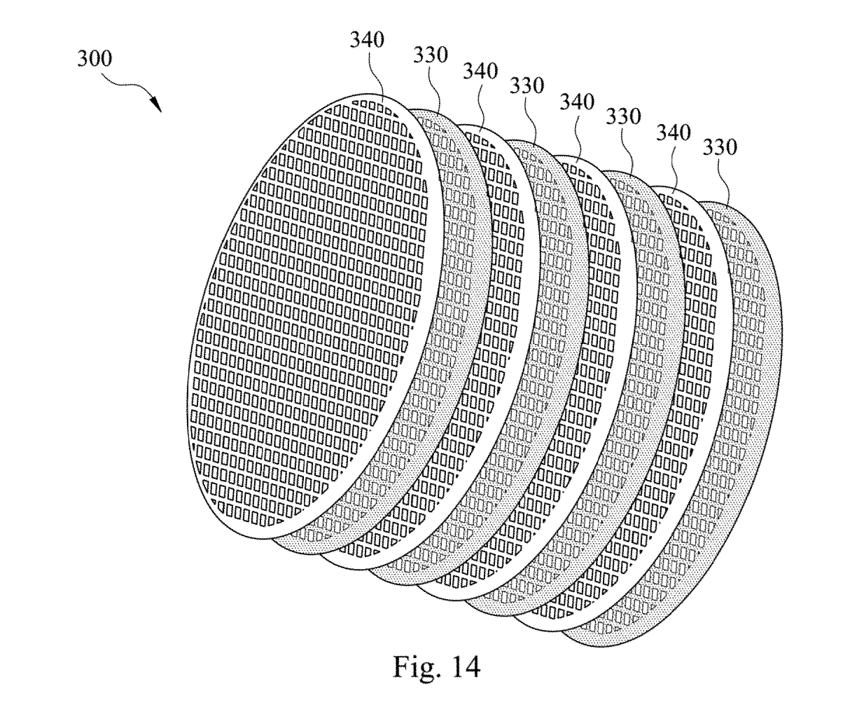

FIG. 11 shows a tellurium/telluride nanowire thermoelectric device 300 constructed by crossly stacking of multiple p-type tellurium/telluride nanowire arrays 330 and multiple n-type tellurium/telluride nanowire arrays 340; FIG. 12 shows voltage outputs varied with temperature differences of the tellurium/telluride nanowire thermoelectric device 300 of FIG. 11; FIG. 13 shows an application example of the tellurium/telluride nanowire thermoelectric device 300 of FIG. 11; FIG. 14 shows another structural example of the tellurium/telluride nanowire thermoelectric device 300 of FIG. 11.

In FIG. 11, the tellurium/telluride nanowire thermoelectric device 300 are formed by crossly stacking of multiple first electrode 310/p-type tellurium/telluride nanowire array 330/second electrode 320 structures and multiple 310/n-type tellurium/telluride nanowire array 340/second electrode 320 structures. The first electrode 310 is fiber shaped, thin-film shaped or sheet shaped, thus a large area of the tellurium/telluride nanowire thermoelectric device 300 can be formed. In FIG. 12, it is shown that the tellurium/telluride nanowire thermoelectric device 300 is used for generating electricity. The dimension of the tellurium/telluride nanowire thermoelectric device 300 is 1 cm*1.5 cm. When 10 layers of p-type tellurium/telluride nanowire arrays 330 and n-type tellurium/telluride nanowire arrays 340 are crossly stacked, the voltage output can reach 127 mV while the temperature difference is 50° C. In one application example, as in FIG. 13, the tellurium/telluride nanowire thermoelectric device 300 can be spread on an internal combustion engine of a car or a motorcycle for collecting thermal energy.

FIG. 14 shows another structural example of the tellurium/telluride nanowire thermoelectric device 300 of FIG. 11. In FIG. 14, the tellurium/telluride nanowire thermoelectric device 300 is flexible and is circle arc shaped. In some examples, the tellurium/telluride nanowire thermoelectric device 300 can be any kinds of geometries. The application examples of the tellurium/telluride nanowire thermoelectric device 300 are shown in the following paragraph.

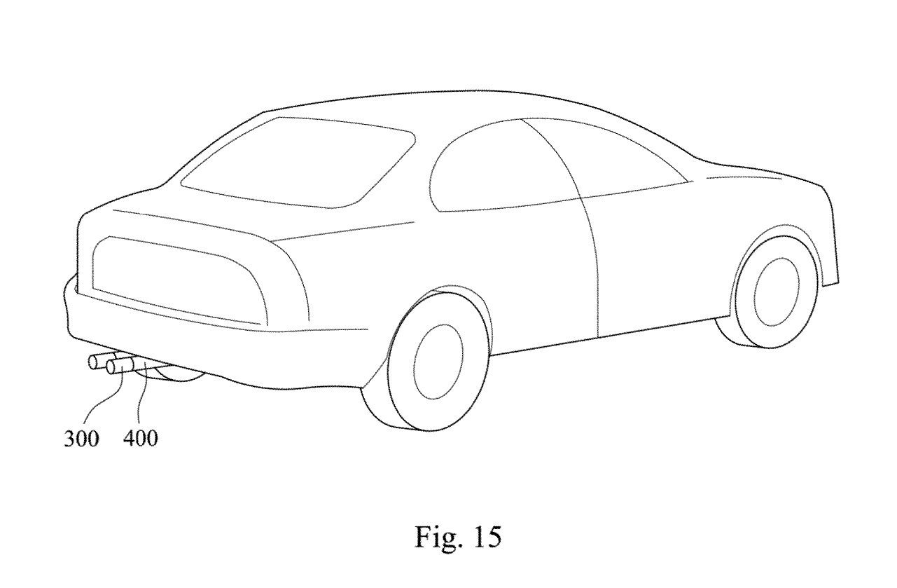

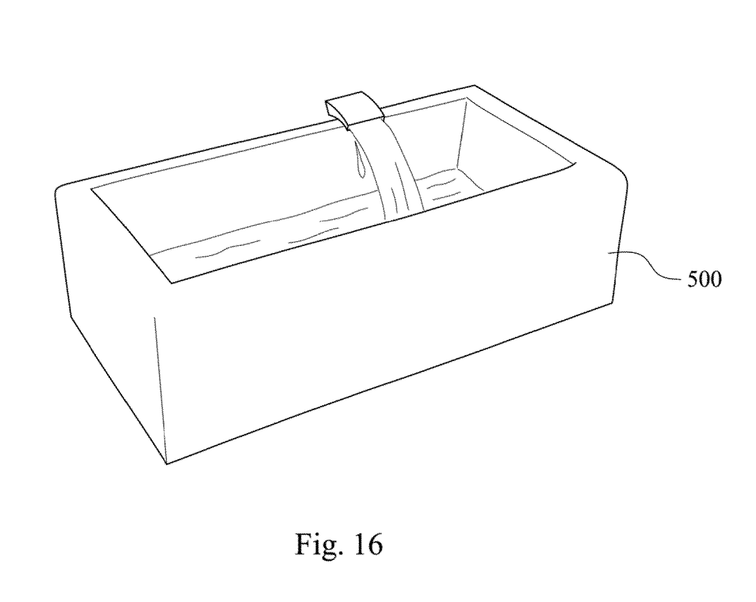

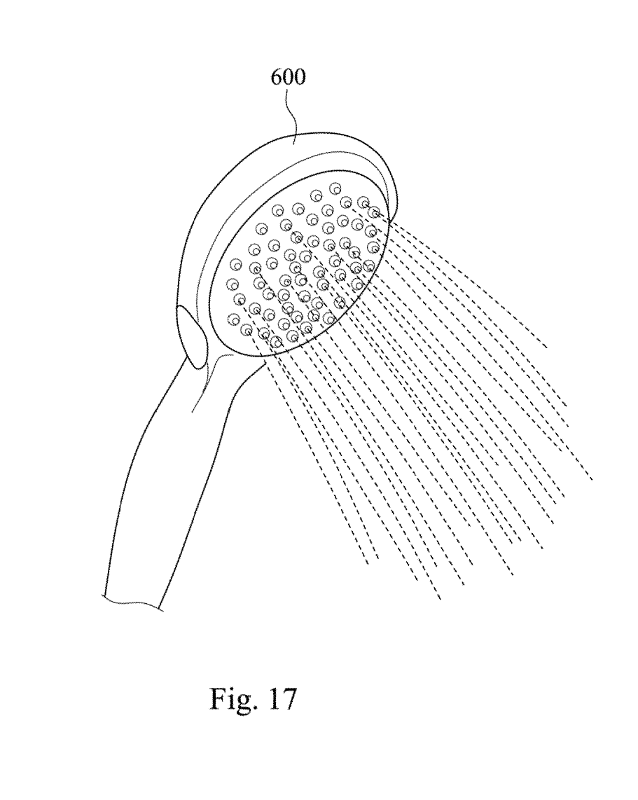

FIG. 15 shows an application example of the tellurium/telluride nanowire thermoelectric device 300 of FIG. 14; FIG. 16 shows another application example of the tellurium/telluride nanowire thermoelectric device 300 of FIG. 14; FIG. 17 shows still another application example of the tellurium/telluride nanowire thermoelectric device 300 of FIG. 14.

In FIG. 15, the tellurium/telluride nanowire thermoelectric device 300 is surrounded on an exhaust pipe 400 of a car or a motorcycle for collecting the thermal energy of the exhaust gas. In FIG. 16, the tellurium/telluride nanowire thermoelectric device 300 is used to collect the thermal energy of the Industrial wastewater in the waste water tank 500. In FIG. 17, the tellurium/telluride nanowire thermoelectric device 300 is used to collect the thermal energy of the water flowed from the shower head 600.

Based on the thermoelectric effect, the aforementioned the tellurium/telluride nanowire thermoelectric device 300 is not only capable of collecting thermal energy but also providing cooling effect. For example, the tellurium/telluride nanowire thermoelectric device 300 can be assembled with an electric chip for cooling the electric chip. In another embodiment, the aforementioned the tellurium/telluride nanowire thermoelectric device 300 also can act as a temperature controlling device.

In sum, in the present disclosure, the method for forming tellurium/telluride nanowire arrays on a conductive substrate and the tellurium/telluride nanowire thermoelectric device have the following advantages: (a) the manufacturing cost is low and the manufacturing processes are simple, and a large area of the tellurium/telluride nanowire array can be produced at one time; (b) organic solvents are not required in the manufacturing processes, thus the environmental requirements can be met; (c) the tellurium/telluride nanowire thermoelectric device is thin and portable, thus it can be applied on many kinds of objects; (d) by selecting the tellurium/telluride nanowire thermoelectric materials having the same lattice directions, the thermal conductivity can be lowered and the thermoelectric conversion efficiency can be increased; (e) the tellurium/telluride nanowire arrays can be selected as n-type or p-type.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method for forming tellurium/telluride nanowire arrays on a conductive substrate, wherein the method is used for forming tellurium/telluride nanowire thermoelectric materials and producing thermoelectric devices, the method comprises:
preparing a conductive substrate;
preparing a mixture solution comprising a tellurium precursor and a reducing agent;
immersing the conductive substrate into the mixture solution;
reacting the tellurium precursor and the reducing agent for forming a plurality of tellurium/telluride nanowires on the conductive substrate; and
arranging the tellurium/telluride nanowires for forming tellurium/telluride nanowire arrays.

2. The method of claim 1, wherein the conductive substrate is rigid or flexible.

3. The method of claim 1, wherein the conductive substrate is fiber shaped, thin-film shaped, bulk shaped, sheet shaped, irregularly shaped, mesh shaped or porously shaped.

4. The method of claim 3, wherein the conductive substrate is mesh shaped or fiber shaped and comprises crossly arranged substrate units, and the tellurium/telluride nanowires are surrounded on a surface of the conductive substrate.

5. The method of claim 1, wherein the conductive substrate has strong reducibility, and the conductive substrate is made from lithium, rubidium, potassium, cesium, barium, strontium, calcium, sodium, magnesium, aluminum, manganese, beryllium or carbon.

6. The method of claim 1, wherein the tellurium/telluride nanowire arrays are formed on the conductive substrate in a large scale.

7. The method of claim 1, wherein the tellurium/telluride nanowire arrays are formed at room temperature.

8. The method of claim 1, further comprising:
changing a concentration ratio of the tellurium precursor and the reducing agent thereby adjusting a length and a width of each of the tellurium/telluride nanowires.

9. The method of claim 1, wherein the tellurium precursor is made from Te [symbol] TeO [symbol] TeO₂ [symbol] TeO₃ [symbol] Te₂O₅ [symbol] H₂TeO₃ [symbol] K₂TeO₃ [symbol] Na₂TeO₃ [symbol] H₂TeO₄ [symbol] K₂TeO₄ [symbol] Na₂TeO₄ [symbol] H₂Te [symbol] NaHTe [symbol] (NH₄)₂Te [symbol] TeCl₄ [symbol] MezTe [symbol] [symbol] Zn(TePh)₂(tmeda) [symbol] (tmeda=N,N,N′,N′-teramethylethylenediamine) or Ph₂SbTeR (R=Et, Ph).

10. A tellurium/telluride nanowire thermoelectric device, comprising:
a first electrode;
at least one tellurium/telluride nanowire array formed on the first electrode; and
a second electrode formed on the at least one tellurium/telluride nanowire array.

11. The tellurium/telluride nanowire thermoelectric device of claim 10, wherein the first electrode is a conductive substrate.

12. The tellurium/telluride nanowire thermoelectric device of claim 11, wherein the tellurium/telluride nanowire thermoelectric device comprises a plurality of tellurium/telluride nanowire arrays, the tellurium/telluride nanowire arrays are p-type or n-type thermoelectric materials formed on the conductive substrate, and the tellurium/telluride nanowire arrays are made from Bismuth telluride [symbol] Lead telluride [symbol] Silver telluride [symbol] Mercury telluride [symbol] Cadmium telluride [symbol] Antimony telluride [symbol] Rubidium telluride [symbol] Manganese(II) telluride [symbol] Zinc telluride [symbol] Lithium Telluride [symbol] Cesium telluride [symbol] Potassium Telluride [symbol] Sodium telluride [symbol] Hydrogen telluride [symbol] Arsenic(III) telluride [symbol] Germanium telluride [symbol] Gold telluride [symbol] Iron telluride [symbol] Palladium telluride [symbol] Lanthanum telluride [symbol] Tin telluride [symbol] Aluminum telluride [symbol] Europium telluride or alloys thereof.

13. The tellurium/telluride nanowire thermoelectric device of claim 10, wherein the tellurium/telluride nanowire thermoelectric device comprises a plurality of stacked p-type tellurium/telluride nanowire arrays and a plurality of n-type tellurium/telluride nanowire arrays stacked or connected with the p-type tellurium/telluride nanowire arrays.

14. The tellurium/telluride nanowire thermoelectric device of claim 10, wherein a conductive polymer is formed between the tellurium/telluride nanowire array and the second electrode, and the conductive polymer is made from polyaniline (PANI), polythiophene (PTH), poly (3, 4-ethylenedioxythiophene):poly (styrenesulfonate) (PEDOT:PSS), polyacetylene (PA), polypyrrole (PPY), polycarbazoles (PC) or polyphenylenevinylene (PPV).

15. The tellurium/telluride nanowire thermoelectric device of claim 10, wherein the second electrode is made from an Indium tin oxide (ITO), Gold (Au), Silver (Ag), Platinum (Pt), Aluminum (Al), Nickel (Ni), Copper (Cu), Titanium (Ti), Chromium (Cr), Selenium (Se) or alloys thereof.
